(19) United States
(12) Patent Application Publication
(10) Pub. No.: US 2025/0150071 A1
(43) Pub. Date: May 8, 2025

(54) DRIVING DEVICE

(71) Applicant: FUJI ELECTRIC CO., LTD., Kanagawa (JP)

(72) Inventor: Masashi AKAHANE, Matsumoto-city (JP)

(21) Appl. No.: 18/893,963

(22) Filed: Sep. 24, 2024

(30) Foreign Application Priority Data
Nov. 8, 2023 (JP) 2023-191151

(51) Int. Cl. H03K 17/0812; H03K 17/08

(52) U.S. Cl. CPC H03K 17/08128; H03K 2017/0806; H03K 2217/0027

(57) ABSTRACT

Provided is a driving device comprising: a driving control unit which, based on a load current or a device temperature of a power semiconductor, controls a driving current of the power semiconductor; and a driver circuit which supplies the power semiconductor with the driving current, wherein the driver circuit comprises: a reference unit which generates a reference current; two or more mirror circuits which are provided in parallel to each other, and each generate a mirror current depending on the reference current; and a current generating unit which, based on currents flowing through the two or more mirror circuits, generates the driving current, and wherein the driving control unit controls whether to cause one or more of the mirror circuits to output the mirror current to the current generating unit to control the driving current.

The contents of the following patent applications are incorporated herein by reference: NO. 2023-191151 filed in JP on Nov. 8, 2023

### BACKGROUND

### 1. Technical Field

The present invention relates to a driving device.

### 2. Related Art

Conventionally, circuits for generating a driving current for driving a target device such as a power semiconductor are known (see, e.g., Patent documents 1 to 3).

### PRIOR ART DOCUMENT

### Patent Document

Patent Document 1: Japanese Patent Application Publication No. 2019-110677
Patent Document 2: Japanese Patent No. 5063124
Patent Document 3: Japanese Patent Application Publication No. 2019-176392

### BRIEF DESCRIPTION OF THE DRAWINGS

FIG. 1 illustrates an example of a power supply device 300 according to one embodiment of the present invention.

FIG. 2 illustrates a configuration example of a driver circuit 128.

FIG. 3 illustrates an operation example of an encoder 122.

FIG. 4 illustrates an operation example of a selecting unit 124.

FIG. 5 illustrates an example of information stored in a control memory 106.

FIG. 6 illustrates an operation example of a driving device 100.

FIG. 7 illustrates an operation example of the driving device 100.

FIG. 8 illustrates an example of a current-slope characteristic.

FIG. 9 illustrates an example of a temperature-loss characteristic.

FIG. 10 illustrates an example of a temperature-slope characteristic.

FIG. 11 illustrates an example of time waveforms of a load current Ic and a voltage across main terminals Vce when turn-on of the power semiconductor 202.

### DESCRIPTION OF EXEMPLARY EMBODIMENTS

Hereinafter, the present invention will be described through embodiments of the invention, but the following embodiments do not limit the invention according to the claims. In addition, not all of the combinations of features described in the embodiments are essential to the solution of the invention. Note that in the present specification and the drawings, elements having substantially the same function and configurations are denoted with a same reference sign to omit duplicated descriptions, and illustrations of elements that are not directly related to the present invention will be omitted. Further, in one drawing, elements having the same functions and configurations are denoted by a representative reference sign, and other reference signs for the elements may be omitted.

In the present specification, a case where a term such as “same” or “equal” is mentioned may include a case where an error due to a variation in manufacturing or the like is included. The error is, for example, within 10%.

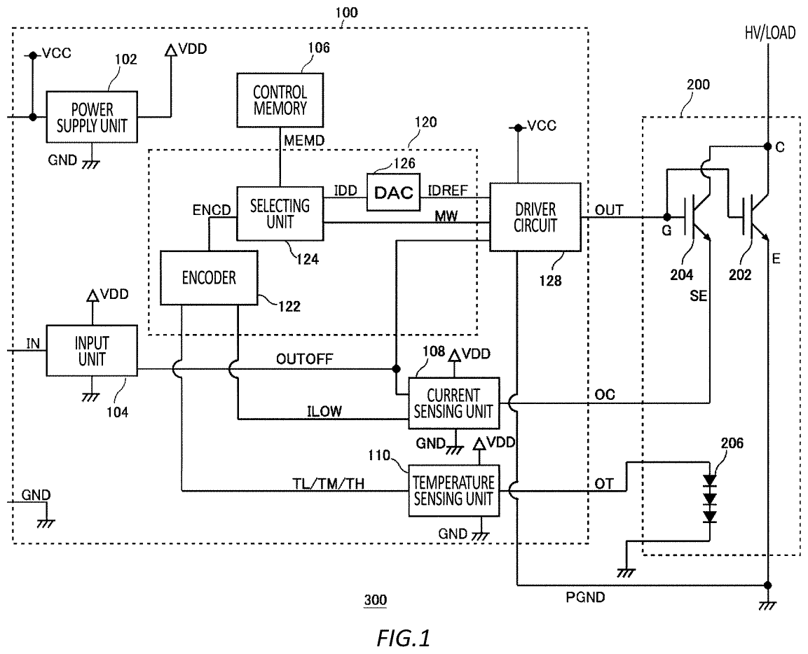

FIG. 1 illustrates an example of a power supply device 300 according to one embodiment of the present invention. The power supply device 300 supplies a load with electrical power. The load is, for example, a circuit provided in a vehicle or an industrial robot, but is not limited thereto. The power supply device 300 includes a driving device 100 and an output device 200.

The output device 200 supplies the load with electrical power. The output device 200 includes a power semiconductor 202. The power semiconductor 202 is, for example, an IGBT, but may be a MOSFET, or may be another device. The power semiconductor 202 of the present example is an IGBT of which a collector terminal C is connected to the load. When the power semiconductor 202 is a circuit of a lower arm, the collector terminal C of the power semiconductor 202 may be connected to a power semiconductor of an upper arm.

The output device 200 of the present example further includes a current-extracting power semiconductor 204 and a temperature sensor 206. The current-extracting power semiconductor 204 retrieves a current value for sensing a current flowing through the power semiconductor 202 at a current sensing unit 108. The current-extracting power semiconductor 204 of the present example is a semiconductor element electrically connected in parallel to the power semiconductor 202. The current-extracting power semiconductor 204 may be a semiconductor element having a configuration similar to that of the power semiconductor 202. Both of the power semiconductor 202 and the current-extracting power semiconductor 204 may be the IGBT, or may be the MOSFET.

The collector terminals C of the power semiconductor 202 and the current-extracting power semiconductor 204 of the present example are connected to each other and gate terminals G thereof are connected to each other. The current-extracting power semiconductor 204 may be provided on a semiconductor substrate that is the same as the one on which the power semiconductor 202 is provided. An area occupied by the current-extracting power semiconductor 204 in the semiconductor substrate is smaller than an area occupied by the power semiconductor 202. Depending on a ratio of these areas, a ratio of currents flowing through the power semiconductor 202 and the current-extracting power semiconductor 204 is determined. The current flowing through the current-extracting power semiconductor 204 may be 0.01 times or less than the current flowing through the power semiconductor 202, or may be 0.001 times or less than that. Sensing a magnitude of a current flowing through a sense emitter terminal SE of the current-extracting power semiconductor 204 allows for sensing a magnitude of a load current flowing from an emitter terminal E of the power semiconductor 202 into the load.

The temperature sensor 206 senses a device temperature of the power semiconductor 202. The device temperature is, for example, a temperature at any one location in the power semiconductor 202. As an example, the temperature sensor 206 is provided above the semiconductor substrate of the power semiconductor 202. The temperature sensor 206 may be arranged above an upper surface of the semiconductor substrate via an insulation film. The temperature sensor 206 of the present example is a PN junction diode provided above the semiconductor substrate of the power semiconductor 202. The temperature sensor 206 may be formed of polysilicon. Electrical characteristics such as a forward voltage of the PN junction diode vary by the temperature of the PN junction diode. Sensing the electrical characteristics of the temperature sensor 206 allows for sensing the device temperature of the power semiconductor 202.

The driving device 100 drives the power semiconductor 202. The driving device 100 of the present example controls switching operations of the power semiconductor 202. The driving device 100 includes the current sensing unit 108, a temperature sensing unit 110, a driving control unit 120, and a driver circuit 128. It is enough to include at least one of the current sensing unit 108 or the temperature sensing unit 110 in the driving device 100. The driving device 100 of the present example includes both of the current sensing unit 108 and the temperature sensing unit 110. The driving device 100 may further include at least any of a control memory 106, a power supply unit 102, and an input unit 104.

To the power supply unit 102 applied is a power source voltage Vcc from a power source connected to the driving device 100. The power supply unit 102 generates an internal voltage VDD based on the power source voltage Vcc. To each configuration of the driving device 100, either of the power source voltage Vcc or the internal voltage VDD may be applied as a power source voltage.

An input signal IN is input from a control circuit connected to the driving device 100 to the input unit 104. The input signal IN of the present example is a signal for controlling a timing to switch the power semiconductor 202. For example, the input signal IN is a signal that is at a first voltage level during a period within which the power semiconductor 202 should be in an ON state and at a second voltage level during a period within which the power semiconductor 202 should be in an OFF state. For example, the first voltage level is either one of an H level or an L level, and the second voltage level is the other one of the H level or the L level. The input unit 104 generates an internal signal OUTOFF based on the input signal IN. The internal signal OUTOFF may have a waveform pattern similar to that of the input signal IN. The internal signal OUTOFF may have an amplitude different than that of the input signal IN. As an example, the internal signal OUTOFF has an amplitude depending on the internal voltage VDD.

The driver circuit 128 controls the switching operations of the power semiconductor 202 based on the internal signal OUTOFF. The driver circuit 128 of the present example, based on the internal signal OUTOFF, generates a control signal OUT. The control signal OUT may have a waveform pattern similar to that of the internal signal OUTOFF. The control signal OUT may have an amplitude different than that of the internal signal OUTOFF. As an example, the control signal OUT has an amplitude depending on the power source voltage VCC of the power semiconductor 202 and a reference electric potential PGND of the power semiconductor 202.

The driver circuit 128 supplies the power semiconductor 202 with a driving current according to the control signal OUT. The driving current is a current for changing a switching state of the power semiconductor 202. The driving current of the present example is a current for charging or discharging a gate capacitance of the power semiconductor 202. Depending on an amount of charges accumulated in the gate capacitance of the power semiconductor 202, the power semiconductor 202 turns to the ON state or the OFF state.

The current sensing unit 108 senses the magnitude of the load current supplied from the power semiconductor 202 to the load. The current sensing unit 108 may receive a current signal OC indicating the magnitude of the load current from the output device 200. The current signal OC of the present example is a signal indicating a magnitude of a sense current flowing through the sense emitter terminal SE of the current-extracting power semiconductor 204. The current signal OC may be the sense current itself, or may be a signal obtained by converting the magnitude of the sense current into a voltage value.

The current sensing unit 108 may output a current sensing signal ILOW indicating a state of the load current. For example, the current sensing signal ILOW is a signal indicating a result of a comparison of the load current with a predetermined current threshold. A number of the current thresholds at the current sensing unit 108 may be one, or may be multiple. A possible range of the load current is divided by one or more current thresholds into a plurality of current ranges. The current sensing signal ILOW may be a signal indicating which current range the load current belongs to. The current sensing signal ILOW of the present example indicates which of a first current range IL having relatively small current values or a second current range IH having larger current values than those within the first current range IL the load current belongs to.

The current sensing unit 108 may switch whether to sense the load current based on the internal signal OUTOFF output by the input unit 104. For example, the current sensing unit 108 may sense the load current during a period within which the power semiconductor 202 should be controlled to be in the ON state by the internal signal OUTOFF.

The temperature sensing unit 110 senses the device temperature of the power semiconductor 202. The temperature sensing unit 110 may receive a temperature signal OT indicating the device temperature from the output device 200. The temperature signal OT of the present example is a signal indicating a magnitude of the forward voltage across the PN junction diode included in the temperature sensor 206. The temperature signal OT may be an anode voltage across the PN junction diode.

The temperature sensing unit 110 may output a temperature sensing signal TL/TM/TH indicating a state of the device temperature. For example, the temperature sensing signal TL/TM/TH is a signal indicating a result of a comparison of the device temperature with a predetermined temperature threshold. A number of the temperature thresholds at the temperature sensing unit 110 may be one, or may be multiple. A possible range of the device temperature is divided by one or more temperature thresholds into a plurality of temperature ranges. The temperature sensing signal TL/TM/TH may be a signal indicating which temperature range the device temperature belongs to. The temperature sensing signal TL/TM/TH of the present example indicates which of a first temperature range TL having relatively low temperatures, a second temperature range TM having higher temperatures than those in the first temperature range TL, and a third temperature range TH having higher temperatures than those in the second temperature range TM the device temperature belongs to.

The driving control unit 120, based on the load current and the device temperature, controls the magnitude of the driving current with which the driver circuit 128 supplies the power semiconductor 202. Controlling the magnitude of the driving current allows for controlling a switching speed of the power semiconductor 202. For example, as the driving current gets larger, the gate capacitance of the power semiconductor 202 is charged or discharged faster, thus increasing the switching speed. The driving control unit 120 may control the magnitude of the driving current when the power semiconductor 202 turns to the ON state. In this case, the speed at which the power semiconductor 202 is turned on can be controlled.

There is a tendency that, as the device temperature gets higher, a current flowing through the gate capacitance of the power semiconductor 202 becomes lower. As the current flowing through the gate capacitance gets lower, a switching period such as a turn-on period gets longer, thus increasing a switching loss such as a turn-on loss Eon. The driving control unit 120 may control the driver circuit 128 such that the driving current increases as the device temperature gets higher. This allows for suppressing the increase in the turn-on loss Eon.

When the load current increases or decreases, a switching noise and the switching loss in the power semiconductor 202 also increase or decrease. For example, in a region where the load current is relatively small, the slope of the voltage waveform when turn-on of the power semiconductor 202 becomes steeper, increasing the switching noise. Furthermore, when the load current increases, the switching loss of the power semiconductor 202 increases. The driving control unit 120 may control the driving current to be small in a low current region where the load current is small, and the driving current to be large in a high current region where the load current is large. This allows for suppressing the switching noise in the low current region while reducing the switching loss in the high current region.

The driving control unit 120 controls the driving current depending on a result of sensing including at least one of the load current or the device temperature. The sensing result may be a value of at least one of the load current sensed by the current sensing unit 108 or the device temperature sensed by the temperature sensing unit 110, or may be a combination of the value of the load current and the value of the device temperature. The driving control unit 120 of the present example controls the driving current depending on the combination of the value of the load current and the value of the device temperature.

The control memory 106 records a magnitude of the driving current to be set for each of a plurality of sensed states including the value of at least one of the load current or the device temperature. A sensed state may be the value of at least one of the load current or the device temperature, or may be the combination of the value of the load current and the value of the device temperature. Although, in the present example, the case when the sensed state is the combination of the value of the load current and the value of the device temperature is described, the driving control unit 120 can operate similarly also in the case when the sensed state is the value of the load current or the device temperature.

The sensed state may be preset by a user or the like. The control memory 106 of the present example records the magnitude of the driving current to be set for the sensed states including both of the value of the load current and the value of the device temperature. The control memory 106 may be rewritable for correspondence between the sensed state and the magnitude of the load current. The correspondence may be set by a user of the power supply device 300 or the like based on characteristics of the power semiconductor 202. This allows for controlling various kinds of power semiconductors 202 by a common driving device 100 and allows for reducing the cost of the driving device 100.

The driving control unit 120 of the present example includes an encoder 122 and a selecting unit 124. The driving control unit 120 may further include a DA converter 126. The encoder 122, based on the current sensing signal ILOW and the temperature sensing signal TL/TM/TH, generates an encoding signal ENCD indicating the combination of the values of the load current and the device temperature. In the present example, the current sensing signal ILOW indicates which of the first current range IL and the second current range IH the load current belongs to. Furthermore, the temperature sensing signal TL/TM/TH indicates which of the first temperature range TL, the second temperature range TM, and the third temperature range TH the device temperature belongs to. The encoder 122 of the present example generates the encoding signal ENCD indicating which current range the load current belongs to and which temperature range the device temperature belongs to.

The selecting unit 124, based on the encoding signal ENCD, outputs a signal for setting the magnitude of the driving current. The selecting unit 124 of the present example reads out from the control memory 106 a setting recording signal MEMD indicating the magnitude of the driving current corresponding to the encoding signal ENCD. The selecting unit 124, based on the setting recording signal MEMD, outputs a setting signal for setting the magnitude of the driving current. The setting signal of the present example includes a first setting signal IDD and a second setting signal MW. The DA converter 126 converts the first setting signal IDD in digital form into a first setting signal IDREF in analog form.

The driver circuit 128 of the present example generates two or more mirror currents depending on a reference current, and selectively merges the two or more mirror current, thus generating the driving current depending on the reference current. The magnitude of the driving current has a predetermined ratio with respect to the magnitude of the reference current. The first setting signal IDD and the first setting signal IDREF are signals for setting the magnitude of the reference current, and the second setting signal MW is a signal for setting the ratio of the driving current with respect to the reference current.

The driver circuit 128, based on the setting signal from the driving control unit 120 and the internal signal OUTOFF from the input unit 104, outputs the control signal OUT. The driver circuit 128 of the present example, when the internal signal OUTOFF indicates that the power semiconductor 202 is to be turned to the ON state, outputs the driving current having the magnitude according to the setting signal. The gate capacitances of the power semiconductor 202 and the current-extracting power semiconductor 204 are charged according to the driving current, t, and then the power semiconductor 202 and the current-extracting power semiconductor 204 transition to the ON state. Adjusting the driving current based on the load current and the device temperature can suppress fluctuations in the turn-on loss due to fluctuations in the load current and the device temperature, and can also suppress the switching noise.

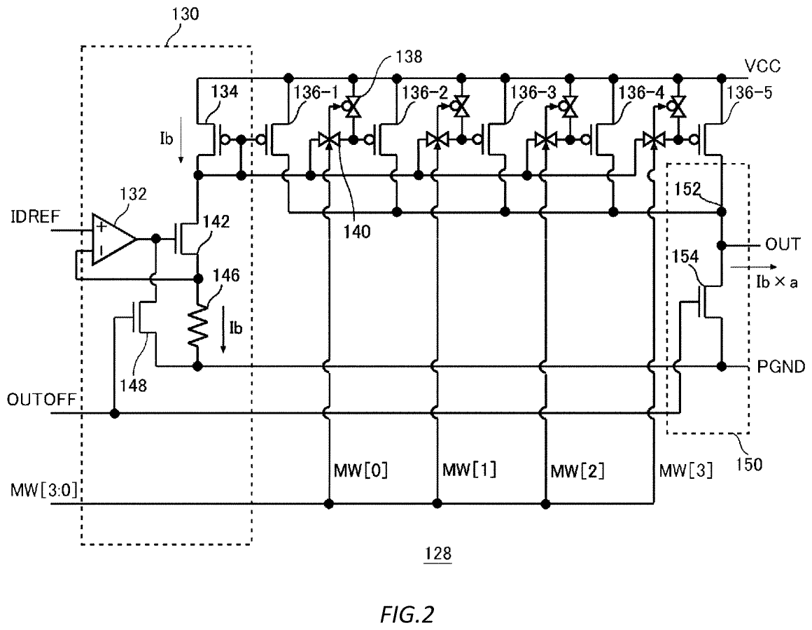

FIG. 2 illustrates a configuration example of the driver circuit 128. The driver circuit 128 includes a reference unit 130, two or more mirror circuits 136, and a current generating unit 150. The driver circuit 128 includes a switch 138 and a switch 140 for at least one mirror circuit 136. The driver circuit 128 of the example in FIG. 2 includes mirror circuits 136-1 to 136-5, but a number of the mirror circuits 136 is not limited thereto.

The reference unit 130 generates a reference current Ib. The reference unit 130 of the present example generates the reference current Ib having the magnitude depending on the first setting signal IDREF. The reference unit 130 of the present example includes a differential circuit 132, a reference circuit 134, a reference current generating unit 142, a resistor 146, and a switching circuit 148.

The reference current generating unit 142 generates the reference current Ib depending on an output of the differential circuit 132. The reference current generating unit 142 of the present example is an n-MOSFET in which the output of the differential circuit 132 is input to its gate terminal. The resistor 146 is arranged between a source terminal of the reference current generating unit 142 and a reference electric potential PGND. The electric potential at the source terminal of the reference current generating unit 142 is a value depending on a magnitude of the reference current Ib.

The differential circuit 132 adjusts a voltage to be input to the gate terminal of the reference current generating unit 142 such that the first setting signal IDREF and the electric potential at the source terminal of the reference current generating unit 142 become the same. This causes the reference current Ib depending on the first setting signal IDREF to flow through the reference current generating unit 142.

The switching circuit 148 switches whether to generate the reference current Ib according to the internal signal OUTOFF. The switching circuit 148 causes the reference current Ib to be generated during the period within which the power semiconductor 202 should be in the ON state, and causes the reference current Ib not to be generated during the period within which the power semiconductor 202 should be in the OFF state. Selectively controlling the period within which the reference current Ib is generated can reduce current consumption by the driver circuit 128. The switching circuit 148 of the present example, during the period within which the power semiconductor 202 should be in the OFF state, applies the reference electric potential PGND to the gate terminal of the reference current generating unit 142. This causes the reference current Ib not to flow through the reference current generating unit 142.

The reference current Ib flows through the reference circuit 134. The reference circuit 134 of the present example is a p-MOSFET directly connected between the reference current generating unit 142 and the power supply wiring VCC on a high-voltage side. A gate terminal and a drain terminal of the reference circuit 134 are connected to each other.

Each of the mirror circuits 136 is connected in parallel to the reference circuit 134. The mirror circuits 136 of the present example each are a p-MOSFET of which a source terminal is connected to the power supply wiring VCC. A drain terminal of each of the mirror circuits 136 is connected to a common node 152. A gate terminal of each of the mirror circuits 136 is connected to the gate terminal of the reference circuit 134.

A gate voltage that is the same as that across the reference circuit 134 is applied across each of the mirror circuits 136, so a mirror current depending on the reference current Ib flows through each of the mirror circuits 136. A ratio of the mirror current flowing through each of the mirror circuits 136 with respect to the reference current Ib is determined by a ratio of a total channel width of the mirror circuit 136 with respect to a total channel width of the reference circuit 134. The ratio may be one, or may be a value other than one. Furthermore, the ratio in each of the mirror circuits 136 may be the same value, or may be a different value.

Each of the switches 140 and the switches 138 switches whether to pass the mirror current through the corresponding mirror circuit 136 or not to pass the mirror current. The switch 140 of the present example switches whether to apply the gate voltage that is the same as that across the reference circuit 134 across the gate terminal of the corresponding mirror circuit 136. The switch 138 switches whether to connect the gate terminal of the corresponding mirror circuit 136 to the power supply wiring VCC. Each of the switches 140 and the switches 138 is controlled by the second setting signal MW.

In the present example, the second setting signal MW contains one or more bits corresponding to at least some of the mirror circuits 136. A logic value of each bit indicates whether to pass the mirror current through the corresponding mirror circuit 136. The second setting signal MW of the present example has bits corresponding to other mirror circuits 136-2 to 136-5 than the mirror circuit 136-1. In this case, the mirror current flows through the mirror circuit 136-1 regardless of the second setting signal MW. The second setting signal MW sets whether to pass the mirror current through for each of the other mirror circuits 136-2 to 136-5.

The current generating unit 150, based on the mirror currents flowing through the two or more mirror circuits 136, generates the driving current. The current generating unit 150 of the present example includes the node 152 and an output control unit 154.

The drain terminal of each of the mirror circuits 136 is connected to the node 152. Thus, the driving current, which is a sum of mirror currents flowing through respective mirror circuits 136, flows through the node 152. Switching whether to pass the mirror current through each of the mirror circuits 136 by the second setting signal MW can control the magnitude of the driving current.

The output control unit 154 controls whether the gate terminals of the power semiconductor 202 and the current-extracting power semiconductor 204 are to be supplied with the driving current, or the gate terminals are to be connected to the reference electric potential PGND. The output control unit 154 of the present example is an n-MOSFET in which the internal signal OUTOFF is input to its gate terminal. When the internal signal OUTOFF is at the L level, the output control unit 154 turns to the OFF state, and the gate terminals of the power semiconductor 202 and the current-extracting power semiconductor 204 are supplied with the driving current. This causes the power semiconductor 202 and the current-extracting power semiconductor 204 to transition to the ON state. When the internal signal OUTOFF is at the H level, the output control unit 154 turns to the ON state, and the gate terminals of the power semiconductor 202 and the current-extracting power semiconductor 204 are connected to the reference electric potential PGND. This causes the power semiconductor 202 and the current-extracting power semiconductor 204 to transition to the OFF state.

Let Ib×a be the magnitude of the driving current. Ib represents the magnitude of the reference current Ib, and a is a scaling factor of the driving current with respect to the reference current. The magnitude of the reference current Ib can be controlled by the first setting signal IDREF. The scaling factor a can be controlled by the second setting signal MW. Controlling at least one of the magnitude of the reference current Ib or the scaling factor a can control the magnitude of the driving current. For example, adjusting the reference current Ib can easily change a variable range of the driving current. Furthermore, adjusting the scaling factor a can easily generate a variety of driving currents within the variable range.

A ratio of the magnitude of the mirror current with respect to the magnitude of the reference current Ib may be different in each of the at least two mirror circuits 136. The ratio may be different in each of all the mirror circuits 136. Let ak be a ratio of the mirror current at the mirror circuit 136-k with respect to the magnitude of the reference current Ib. The magnitude of the ratio ak may be twice the magnitude of the ratio ak-1. This allows for widening the variable range of the driving current compared to the case when the magnitudes of the mirror currents are uniform.

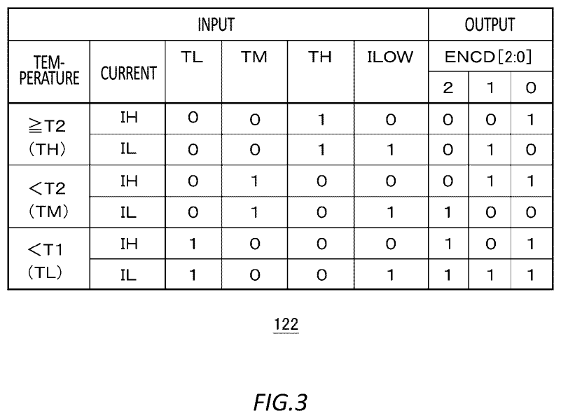

FIG. 3 illustrates an operation example of the encoder 122. The temperature sensing unit 110 of the present example compares the device temperature with one or more temperature thresholds (T1 and T2 in FIG. 3). The temperature threshold T2 of the present example is higher than the temperature threshold T1. Let a first temperature range TL be a region below the temperature threshold T1, a second temperature range TM be a region equal to or above the temperature threshold T1 and below the temperature threshold T2, and a third temperature range TH be a region equal to or above the temperature threshold T2. The temperature sensing signal TL/TM/TH has bits each one of which corresponds to each one of the plurality of temperature ranges. The temperature sensing unit 110 of the present example outputs the temperature sensing signal TL/TM/TH in which the bit representing the temperature range the device temperature belongs to is set to 1, and the other bits are set to 0.

The current sensing unit 108 of the present example compares the load current with one or more current thresholds (one current threshold in the example in FIG. 3). In the present example, let a first current range IL be a region below the current threshold, and a second current range IH be a region equal to or above the current threshold. The current sensing signal ILOW of the present example has a bit indicating which current range the load current belongs to. The current sensing unit 108 of the present example outputs the current sensing signal ILOW in which the bit is set to 1 when the load current belongs to the first current range IL, and the bit is set to 0 when the load current belongs to the second current range IH.

The encoder 122 outputs an encoding signal ENCD indicating how the value of the temperature sensing signal TL/TM/TH and the value of the current sensing signal ILOW are combined. The encoding signal ENCD is a signal that indicates a different value for each combination of the value of the temperature sensing signal TL/TM/TH and the value of the current sensing signal ILOW. The number of bits in the encoding signal ENCD (three bits in the present example) may be less than the total number of bits in the temperature sensing signal TL/TM/TH and the current sensing signal ILOW (four bits in the present example).

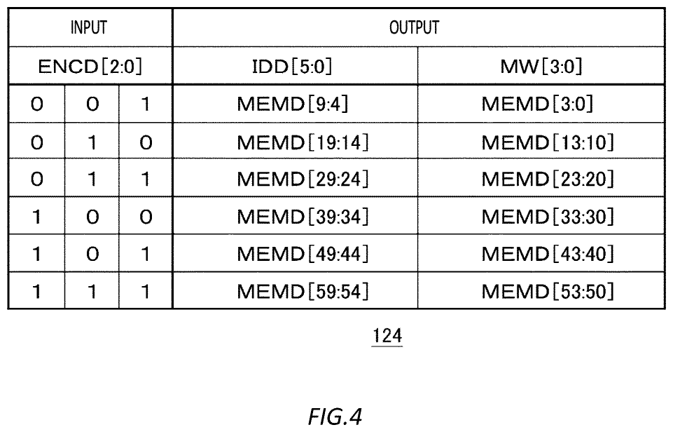

FIG. 4 illustrates an operation example of the selecting unit 124. The encoding signal ENCD is input to the selecting unit 124 of the present example. The selecting unit 124 reads out from the control memory 106 the setting recording signal MEMD corresponding to the encoding signal ENCD to output the first setting signal IDD and the second setting signal MW. In the selecting unit 124, an address in the control memory 106 to be read out is associated with each value of the encoding signal ENCD. The control memory 106 of the example in FIG. 4 has a storage region from 0 to 59 bits. The selecting unit 124 reads out information of bits depending on the encoding signal ENCD.

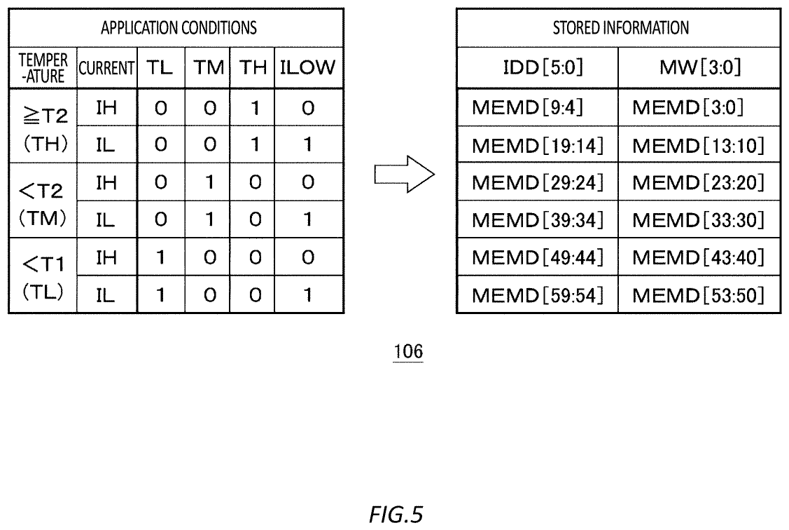

FIG. 5 illustrates an example of information stored in the control memory 106. As described in FIG. 4, the control memory 106 stores the setting recording signal MEMD corresponding to each value of the encoding signal ENCD (that is, the sensed state). As described above, the selecting unit 124 reads out from the control memory 106 the setting recording signal depending on the combination of the values of the temperature sensing signal TL/TM/TH and the current sensing signal ILOW.

The setting recording signal MEMD may be preset by the user or the like depending on characteristics of the power semiconductor 202 to be driven. The control memory 106 is preferably a rewritable memory. This allows for generating the driving current depending on the characteristics of the power semiconductor 202 by simply changing settings of the control memory 106.

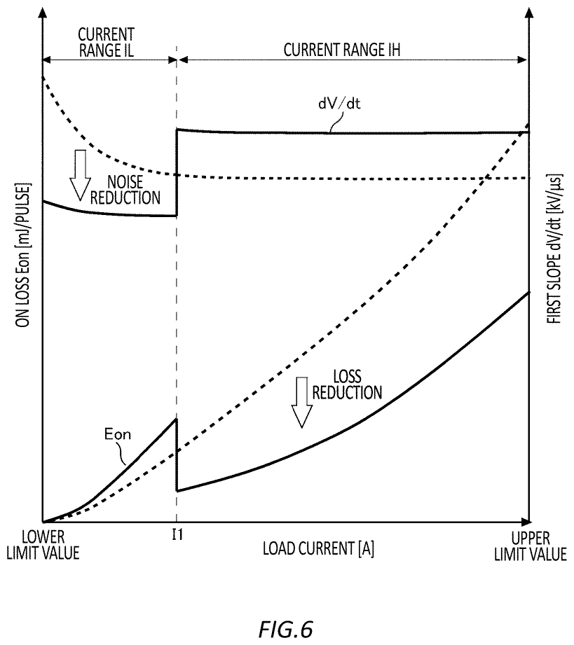

FIG. 6 illustrates an operation example of the driving device 100. In FIG. 6, a current-slope characteristic and a current-loss characteristic of the power semiconductor 202 are illustrated. The current-slope characteristic is a characteristic indicating a relationship between the load current and a first slope dV/dt. When turn-on of the power semiconductor 202, a voltage across main terminals of the power semiconductor 202 changes over time with the first slope dV/dt. The voltage across main terminals of the power semiconductor 202 is, for example, an emitter-collector voltage, or a source-drain voltage.

In FIG. 6, the current-slope characteristic in the case when the driving current is not changed is illustrated by a dashed line. As illustrated in FIG. 6, the first slope dV/dt tends to increase as the load current gets smaller. In FIG. 6, the current-slope characteristic in the case when the driving current is controlled is illustrated by a solid line.

The current-loss characteristic is a characteristic indicating a relationship between the load current and the turn-on loss Eon when turn-on. The turn-on loss Eon is lost energy generated in the power semiconductor 202 from the beginning of turn-on to a point when the voltage across main terminals reaches a set value. The turn-on loss Eon indicates loss in one turn-on (one pulse). In FIG. 6, the current-loss characteristic in the case when the driving current is not changed is illustrated by a dashed line. As illustrated in FIG. 6, the turn-on loss Eon tends to increase as the load current gets greater. In FIG. 6, the current-loss characteristic in the case when the driving current is controlled is illustrated by a solid line.

The driving control unit 120 changes the driving current each time the load current exceeds one or more preset current thresholds. The driving control unit 120 may increase the driving current each time the load current exceeds one or more preset current thresholds. In the example in FIG. 6, one current threshold 11 is illustrated. In the first current range IL where the load current is lower than the current threshold 11, the driving current is controlled to be relatively low. Thus, the first slope dV/dt in the first current range IL becomes relatively small. Thus, the switching noise can be reduced. Furthermore, in the first current range IL, the turn-on loss is not suppressed, but the turn-on loss is originally small in a region where the load current is low. Thus, in the first current range IL, the turn-on loss may not be suppressed by the driving current, or the turn-on loss may increase by the driving current.

The driving control unit 120, when the load current belongs to the second current range IH equal to or above the current threshold 11, increases the driving current compared to that when the load current belongs to the first current range IL below the current threshold 11. This allows for reducing the turn-on loss. Furthermore, in the second current range IH, the switching noise increases according to the increase in the driving current, but the switching noise does not increase so much because the switching noise is originally small in the region where the load current is high. As illustrated in FIG. 6, increasing the driving current according to the increase in the load current can establish the reduction in the turn-on loss and the reduction in the switching noise at the same time.

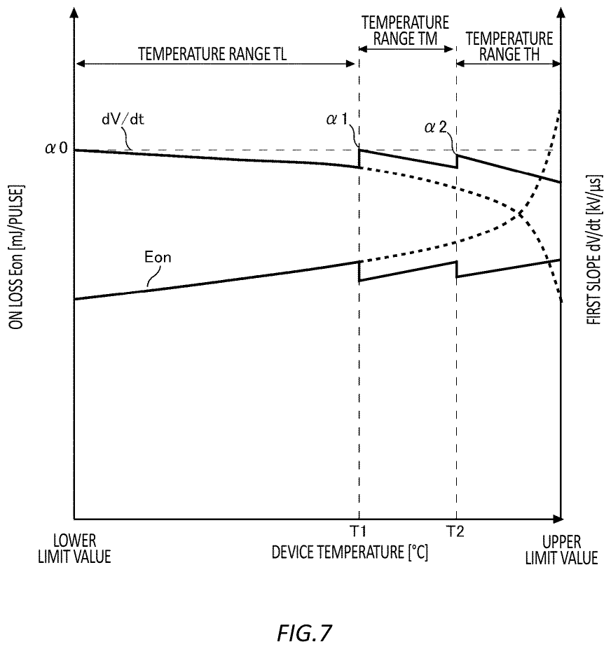

FIG. 7 illustrates an operation example of the driving device 100. In FIG. 7, a temperature-slope characteristic and a temperature-loss characteristic of the power semiconductor 202 are illustrated. The temperature-slope characteristic is a characteristic indicating a relationship between the device temperature and a first slope dV/dt. In FIG. 7, the temperature-slope characteristic in the case when the driving current is not changed is illustrated by a dashed line. As illustrated in FIG. 7, the first slope dV/dt tends to decrease as the device temperature gets higher. In FIG. 7, the temperature-slope characteristic in the case when the driving current is controlled is illustrated by a solid line.

The temperature-loss characteristic is a characteristic indicating a relationship between the device temperature and the turn-on loss Eon. In FIG. 7, the temperature-loss characteristic in the case when the driving current is not changed is illustrated by a dashed line. As illustrated in FIG. 7, the turn-on loss Eon tends to increase as the device temperature gets higher. In FIG. 7, the temperature-loss characteristic in the case when the driving current is controlled is illustrated by a solid line.

The driving control unit 120 changes the driving current each time the device temperature exceeds one or more preset temperature thresholds. The driving control unit 120 may increase the driving current each time the device temperature exceeds one or more preset temperature thresholds. In the example in FIG. 7, two temperature thresholds T1 and T2 are illustrated. In the first temperature range TL where the device temperature is below the temperature threshold T1, the driving current is controlled to be relatively low. The driving control unit 120, in the second temperature range TM where the device temperature is equal to or above the temperature threshold T1 and below the temperature threshold T2, increases the driving current compared to the first temperature range TL. The driving control unit 120, in the third temperature range TH where the device temperature is equal to or above the temperature threshold T2, increases the driving current compared to the second temperature range TM.

Such control can suppress the turn-on loss Eon even when the device temperature increases. Also as illustrated in FIG. 7, each time the device temperature exceeds the temperature thresholds T1 and T2 and the driving current increases, the first slope dV/dt increases and the switching noise increases. The driving control unit 120 may increase the driving current to the extent that the first slope dV/dt is a predetermined value α0 or below.

The predetermined value α0 may be the first slope dV/dt of the power semiconductor 202 in the state where the device temperature of the power semiconductor 202 is a lower limit value of an operational temperature range of the power semiconductor 202 and the driving current is controlled to be a minimum value other than 0 A. The minimum value of the driving current of the present example refers to the minimal one among the magnitudes of the driving current corresponding to the setting recording signal MEMD stored in the control memory 106. That is, it refers to the minimal one among the driving currents the driver circuit 128 can generate. Note that the magnitude of the driving current is greater than 0 A.

The driving control unit 120, when the device temperature increases to reach the temperature threshold T1, increases the driving current. Let a1 be the magnitude of the first slope dV/dt at this time. Similarly, let α2 be the magnitude of the first slope dV/dt when the device temperature reaches the temperature threshold T2 to increase the driving current. An amount of increase in the driving current may be set such that both α1 and α2 are equal to or below the predetermined value α0. α2 may be the same as or different than a1. Such control can suppress the increase in the switching noise while reducing the turn-on loss Eon.

The lower limit value of the load current in FIG. 6 may be 0 A. An upper limit value of the load current may be a rated current of the power semiconductor 202. The lower limit value and the upper limit value of the device temperature in FIG. 7 may be a lower limit value and an upper limit value in an operational temperature range determined by the specification of the power semiconductor 202.

The characteristics illustrated in FIG. 7 are characteristics in the case when the load current is a predetermined value. When the load current changes, as illustrated in FIG. 6, the values of the turn-on loss Eon and the first slope dV/dt change. Thus, when the load current changes, the values of the turn-on loss and the first slope dV/dt illustrated in FIG. 7 shift. Similarly, when the device temperature changes, the values of the turn-on loss and the first slope dV/dt illustrated in FIG. 6 shift.

As the current thresholds described in FIG. 6, a common value may be used even if the device temperature changes. In another example, a different value may be used as the current thresholds depending on the device temperature. For example, as the device temperature gets higher, the turn-on loss increases. Thus, the current-loss characteristic illustrated in FIG. 6 shifts upward. The driving control unit 120 may have a smaller current threshold as the device temperature gets higher. This facilitates to suppress the turn-on loss.

As the temperature thresholds described in FIG. 7, a common value may be used even if the load current changes. In another example, a different value may be used as the temperature thresholds depending on the load current. For example, as the load current gets higher, the turn-on loss increases. Thus, the temperature-loss characteristic illustrated in FIG. 7 shifts upward. The driving control unit 120 may have a smaller temperature threshold as the load current gets higher. This facilitates to suppress the turn-on loss.

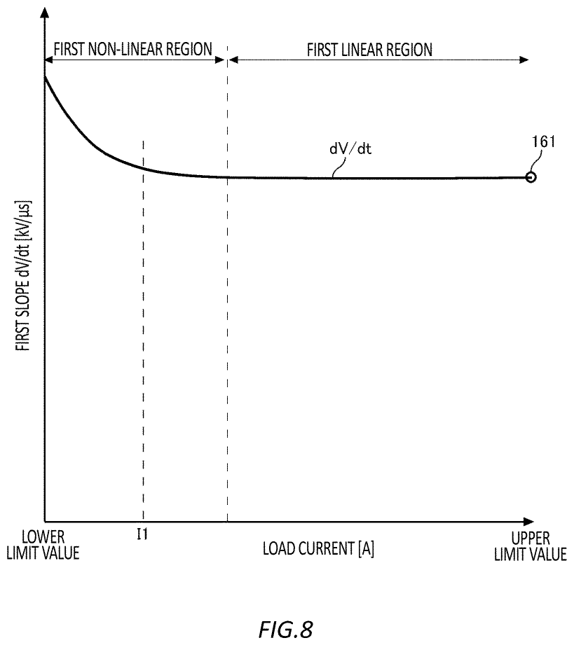

FIG. 8 illustrates an example of the current-slope characteristic. The current-slope characteristic in FIG. 8 is similar to that of the example in FIG. 6. The current-slope characteristic has a first linear region where the first slope dV/dt linearly changes for the load current and a first non-linear region where the first slope dV/dt non-linearly changes for the load current. The first non-linear region is a region where the load current is lower than that in the first linear region. As illustrated in FIG. 8, in a region where the load current is close to an upper limit value, the first slope dV/dt linearly increases with the decrease in the load current. On the other hand, in a region where the load current is close to a lower limit value, the first slope dV/dt non-linearly increases with the decrease in the load current.

The first linear region may be a region where a differential value obtained by differentiating a waveform of the current-slope characteristic using the load current is within a predetermined range with respect to a reference value. That is, a region where the differential value is approximately equal to the reference value may be the first linear region. A differential value at a reference point 161 in the waveform of the current-slope characteristic may be used as the reference value. The reference point 161 may be a point at which the load current exhibits the upper limit value. The predetermined range may be, for example, ±50%, ±30%, or ±10% of the reference value.

At least one current threshold may have been set in the first non-linear region. In the example in FIG. 8, the current threshold 11 has been set in the first non-linear region. In the first non-linear region, the degree of decrease in the first slope dV/dt is large due to decreasing the driving current. Thus, setting the current threshold 11 in the first non-linear region can effectively suppress the switching noise. All current thresholds may be set in the first non-linear region, or some of the current thresholds may be set in the first linear region. A number of the current thresholds set in the first non-linear region may be greater than a number of the current thresholds set in the first linear region.

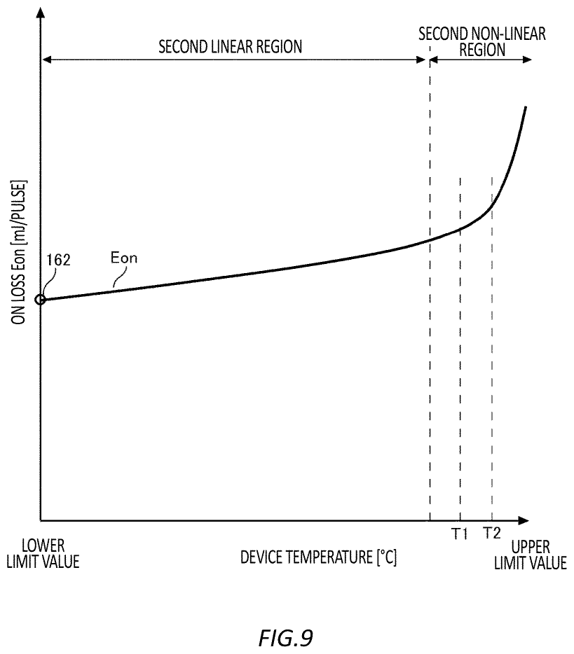

FIG. 9 illustrates an example of the temperature-loss characteristic. The temperature-loss characteristic in FIG. 9 is similar to that of the example in FIG. 7. The temperature-loss characteristic has a second linear region where the turn-on loss Eon linearly changes for the device temperature and a second non-linear region where the turn-on loss Eon non-linearly changes for the device temperature. The second non-linear region is a region where the device temperature is higher than that in the second linear region. As illustrated in FIG. 9, in a region where the device temperature is close to a lower limit value, the turn-on loss Eon linearly increases with the increase in the device temperature. On the other hand, in a region where the device temperature is close to an upper limit value, the turn-on loss Eon non-linearly increases with the increase in the device temperature.

The second linear region may be a region where a differential value obtained by differentiating a waveform of the temperature-loss characteristic using the device temperature is within a predetermined range with respect to a reference value. That is, a region where the differential value is approximately equal to the reference value may be the second linear region. A differential value at a reference point 162 in the waveform of the temperature-loss characteristic may be used as the reference value. The reference point 162 may be a point at which the device temperature exhibits the lower limit value. The predetermined range may be, for example, ±50%, ±30%, or ±10% of the reference value.

At least one temperature threshold may have been set in the second non-linear region. In the example in FIG. 9, temperature thresholds T1 and T2 have been set in the second non-linear region. In the second non-linear region, the degree of suppression in the turn-on loss is large due to increasing the driving current. Thus, setting the temperature thresholds in the second non-linear region can effectively suppress the turn-on loss. All temperature thresholds may be set in the second non-linear region, or some of the temperature thresholds may be set in the second linear region. A number of the temperature thresholds set in the second non-linear region may be greater than a number of the temperature thresholds set in the second linear region.

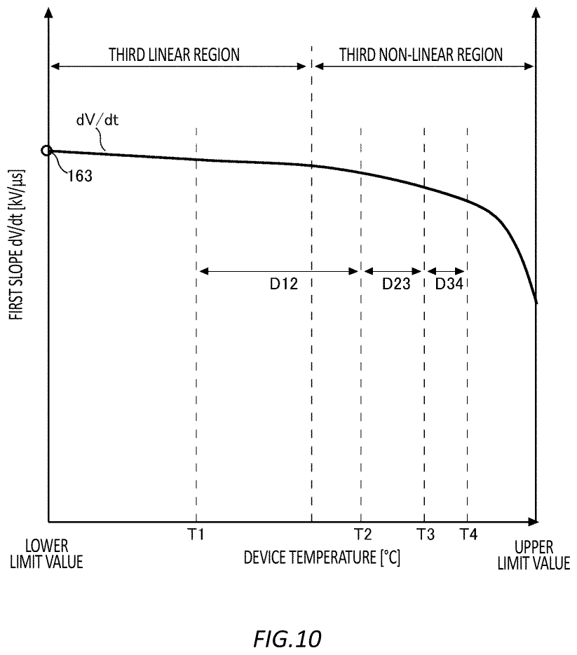

FIG. 10 illustrates an example of the temperature-slope characteristic. The temperature-slope characteristic in FIG. 10 is similar to that of the example in FIG. 7. The temperature-slope characteristic has a third linear region where the first slope dV/dt linearly changes for the device temperature and a third non-linear region where the first slope dV/dt non-linearly changes for the device temperature. The third non-linear region is a region where the device temperature is higher than that in the third linear region. As illustrated in FIG. 10, in a region where the device temperature is close to a lower limit value, the first slope dV/dt linearly decreases with the increase in the device temperature. On the other hand, in a region where the device temperature is close to an upper limit value, the first slope dV/dt non-linearly decreases with the increase in the device temperature.

The third linear region may be a region where a differential value obtained by differentiating a waveform of the temperature-slope characteristic using the device temperature is within a predetermined range with respect to a reference value. That is, a region where the differential value is approximately equal to the reference value may be the third linear region. A differential value at a reference point 163 in the waveform of the temperature-slope characteristic may be used as the reference value. The reference point 163 may be a point at which the device temperature exhibits the lower limit value. The predetermined range may be, for example, ±50%, ±30%, or ±10% of the reference value.

At least one temperature threshold may have been set in the third non-linear region. In the example in FIG. 10, temperature thresholds T2 to T4 have been set in the third non-linear region. As described in FIG. 7, as the driving current increases, the first slope dV/dt increases, and in turn the switching noise increases, whereas the turn-on loss can be reduced. For example, increasing the driving current to the extent that the first slope dV/dt does not exceed the reference value α0 can suppress the increase in the switching noise while reducing the turn-on loss. Therefore, increasing the driving current each time the first slope dV/dt decreases by an amount with respect to the reference value α0 can efficiently reduce the turn-on loss. As in the third non-linear region, in a region where the decreasing amount in the first slope dV/dt for a particular increase in the device temperature, narrowing intervals between the temperature thresholds can increase the driving current before the first slope dV/dt becoming too small. Thus, the turn-on loss can be efficiently reduced. Also, as in the third non-linear region, in the region where the decreasing amount in the first slope dV/dt for the particular increase in the device temperature, broadening the intervals between the temperature thresholds too much causes the variation of the first slope dV/dt to be too large when the device temperature exceeds the temperature threshold, possibly generating the noises or the like.

A number of the temperature thresholds set in the third non-linear region may be greater than a number of the temperature thresholds set in the third linear region. In the present example, the temperature threshold T1 has been set in the third linear region. A density of the temperature thresholds set in the third non-linear region may be greater than a density of the temperature thresholds set in the third linear region. The density of the temperature thresholds is a value obtained by dividing a number of the temperature thresholds included in each region by a length of the temperature range for each region.

The temperature threshold described in each example herein may be such that a difference between two temperature thresholds adjacent to each other is smaller as the temperature thresholds are higher. In this case, three or more temperature thresholds are set. The phrase “the two temperature thresholds adjacent to each other” refers to two temperature thresholds adjacent to each other when a plurality of temperature thresholds are arranged on a temperature axis. In the example in FIG. 10, the temperature thresholds T1, T2, T3, and T4 are arranged on the temperature axis from the lower limit value to the upper limit value. A difference between the temperature thresholds T3 and T4 may be smaller than a difference between the temperature thresholds T1 and T2. That is, a difference between two temperature thresholds having highest temperatures may be smaller than a difference between two temperature thresholds having lowest temperatures.

A difference between two temperature thresholds adjacent to each other in the third non-linear region may be smaller than a difference between two temperature thresholds adjacent to each other in the third linear region. The two temperature thresholds adjacent to each other in the third non-linear region may be both included in the third non-linear region. The two temperature thresholds adjacent to each other in the third linear region may be both included in the third linear region. In the example in FIG. 10, when the temperature threshold T1 is the only one that is set in the third linear region, a difference D12 between the temperature threshold T2 that is next to the temperature threshold T1, and the temperature threshold T1 may be used as the difference between the two temperature thresholds adjacent to each other in the third linear region.

In the example in FIG. 10, a value of a difference D23 between the temperature thresholds T2 and T3 is smaller than the value of the difference D12. A value of a difference D34 between the temperature thresholds T3 and T4 is smaller than the value of the difference D12. The value of the difference D34 may be smaller than the value of the difference D23, or may be the same as the value of the difference D23.

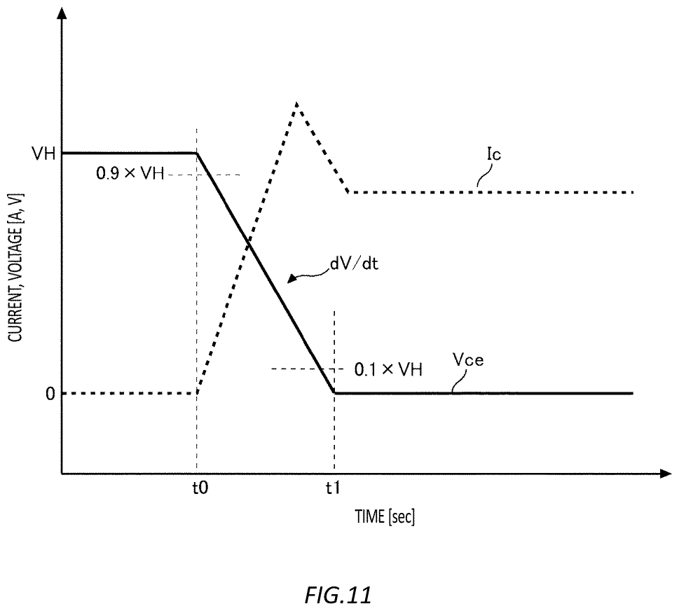

FIG. 11 illustrates an example of time waveforms of a load current Ic and a voltage across main terminals Vce when turn-on of the power semiconductor 202. When the gate terminal of the power semiconductor 202 is supplied with the driving current and the threshold voltage of the power semiconductor 202 is exceeded at time t0, the load current Ic increases, and the voltage across main terminals Vce decreases from a voltage when OFF (VH in the present example) to a reference voltage (0 V in the present example).

As used herein, let the first slope dV/dt be an absolute value of a slope of the waveform of the voltage across main terminals Vce when the voltage across main terminals Vce decreases from 0.9×VH to 0.1×VH when turn-on. Furthermore, let the turn-on loss Eon be energy loss in the power semiconductor 202 within a period where the voltage across main terminals Vce decreases from VH to 0 V.

While the present invention has been described by way of the embodiments, the technical scope of the present invention is not limited to the scope described in the above-described embodiments. It is apparent to persons skilled in the art that various alterations or improvements can be made to the above-described embodiments. It is also apparent from the described scope of the claims that the embodiments added with such alterations or improvements can be included the technical scope of the present invention.

What is claimed is:

1. A driving device of a power semiconductor, comprising:
at least one of a current sensing unit which senses a magnitude of a load current supplied from the power semiconductor to a load, or a temperature sensing unit which senses a device temperature of the power semiconductor;
a driving control unit which, based on at least one of the load current or the device temperature, controls a driving current of the power semiconductor; and
a driver circuit which supplies the power semiconductor with the driving current,
wherein the driver circuit comprises:
a reference unit which generates a reference current;
two or more mirror circuits which are provided in parallel to each other, and each generate a mirror current depending on the reference current; and
a current generating unit which, based on currents flowing through the two or more mirror circuits, generates the driving current, and
wherein the driving control unit controls whether to cause one or more of the mirror circuits to output the mirror current to the current generating unit to control the driving current.

2. The driving device according to claim 1, wherein the driving control unit controls a magnitude of the reference current to control the driving current.

3. The driving device according to claim 1, wherein a ratio of the mirror current with respect to the reference current varies in each of at least two of the mirror circuits.

4. The driving device according to claim 1, further comprising:
a control memory which has recorded the driving current to be set for each of a plurality of sensed states including at least one of the load current or the device temperature,
wherein the driving control unit, based on a sensed state of the plurality of the sensed states corresponding to a sensed value of at least one of the load current or the device temperature, reads out from the control memory a setting recording signal indicating the driving current.

5. The driving device according to claim 1, wherein the driving control unit changes the driving current each time the load current exceeds one or more preset current thresholds.

6. The driving device according to claim 5, wherein, when turn-on of the power semiconductor, a voltage across main terminals of the power semiconductor changes over time with a first slope,
wherein a current-slope characteristic, which is a characteristic of the first slope for the load current, has a first linear region where the first slope linearly changes for the load current and a first non-linear region where the first slope non-linearly changes for the load current in a region where the load current is lower than that in the first linear region, and
wherein at least one of the current thresholds has been set in the first non-linear region.

7. The driving device according to claim 1, wherein the driving control unit changes the driving current each time the device temperature exceeds one or more preset temperature thresholds.

8. The driving device according to claim 7, wherein a temperature-loss characteristic, which is a characteristic of a turn-on loss of the power semiconductor for the device temperature, has a second linear region where the turn-on loss linearly changes for the device temperature and a second non-linear region where the turn-on loss non-linearly changes for the device temperature in a region where the device temperature is higher than that in the second linear region, and
wherein at least one of the temperature thresholds has been set in the second non-linear region.

9. The driving device according to claim 4, wherein, when turn-on of the power semiconductor, a voltage across main terminals of the power semiconductor changes over time with a first slope,
wherein an operational temperature range has been set in the power semiconductor, and
wherein the driving control unit controls the driving current such that the first slope when increasing the driving current is equal to or less than the first slope when the device temperature is a lower limit value of the operational temperature range and the driving current is a minimum value.

10. The driving device according to claim 7, wherein three or more temperature thresholds have been set as the temperature thresholds, and
wherein a difference between the temperature thresholds adjacent to each other is smaller as the temperature thresholds are higher.

11. The driving device according to claim 10, wherein, when turn-on of the power semiconductor, a voltage across main terminals of the power semiconductor changes over time with a first slope,
wherein a temperature-slope characteristic, which is a characteristic of the first slope for the device temperature, has a third linear region where the first slope linearly changes for the device temperature and a third non-linear region where the first slope non-linearly changes for the device temperature in a region where the device temperature is higher than that in the third linear region, and
wherein a difference between the temperature thresholds adjacent to each other in the third non-linear region is smaller than a difference between the temperature thresholds adjacent to each other in the third linear region.

12. A driving device of a power semiconductor, comprising:
a current sensing unit which senses a magnitude of a load current supplied from the power semiconductor to a load;
a temperature sensing unit which senses a device temperature of the power semiconductor;
a driving control unit which, based on the load current and the device temperature, controls a driving current of the power semiconductor; and
a control memory which has recorded the driving current to be set for each of a plurality of combinations of a value of the load current and a value of the device temperature,
wherein the driving control unit reads out from the control memory a setting recording signal indicating the driving current corresponding to a sensed combination of the value of the load current and the value of the device temperature.

13. The driving device according to claim 2, wherein the driving control unit changes the driving current each time the load current exceeds one or more preset current thresholds.

14. The driving device according to claim 3, wherein the driving control unit changes the driving current each time the load current exceeds one or more preset current thresholds.

15. The driving device according to claim 4, wherein the driving control unit changes the driving current each time the load current exceeds one or more preset current thresholds.

16. The driving device according to claim 2, wherein the driving control unit changes the driving current each time the device temperature exceeds one or more preset temperature thresholds.

17. The driving device according to claim 3, wherein the driving control unit changes the driving current each time the device temperature exceeds one or more preset temperature thresholds.

18. The driving device according to claim 4, wherein the driving control unit changes the driving current each time the device temperature exceeds one or more preset temperature thresholds.
